(19) United States
(12) Patent Application Publication
(10) Pub. No.: US 2026/0123439 A1
(43) Pub. Date: Apr. 30, 2026

(54) PACKAGE STRUCTURE

(71) Applicant: Advanced Semiconductor Engineering, Inc., Kaohsiung (TW)

(72) Inventors: Yuanhao YU, Kaohsiung (TW); Weifan WU, Kaohsiung (TW); Yong-Chang SYU, Kaohsiung (TW); Chien-Hua WANG, Kaohsiung (TW); Chung Ju YU, Kaohsiung (TW)

(73) Assignee: Advanced Semiconductor Engineering, Inc., Kaohsiung (TW)

(21) Appl. No.: 18/926,244

(22) Filed: Oct. 24, 2024

(51) Int. Cl. H01L 23/552; H01L 23/00; H01L 23/31; H01L 25/10

(52) U.S. Cl. CPC H10W 42/20; H10W 74/111; H10W 90/00; H10W 74/15; H10W 90/724; H10W 90/734

(57) ABSTRACT

A package structure is provided. The package structure includes a first electronic component, a first shielding layer, a second shielding layer, and an electrical connection element. The first shielding layer is over a lateral sidewall of the first electronic component. The second shielding layer is at a lateral side of the first shielding layer and spaced apart from the first shielding layer. The electrical connection element includes a reflowable material between the first shielding layer and the second shielding layer. The first shielding layer overlaps the second shielding layer in a direction substantially parallel to a top surface of the second shielding layer. An elevation of an upper surface of the electrical connection element is lower than at least one of an elevation of a top surface of the first shielding layer and an elevation of the top surface of the second shielding layer with respect to a bottom surface of the first electronic component.

### BACKGROUND

### 1. Technical Field

The present disclosure relates generally to a package structure.

### 2. Description of the Related Art

Typically, in high-density semiconductor packaging, multiple dies or modules having different wafer nodes may be disposed within a package structure, and the dies or modules may be grouped and encapsulated separately according to the wafer nodes to be bonded to a substrate during the packaging process to increase the yield. For example, some of the dies or modules having the same wafer node can be arranged side-by-side or can be stacked vertically within a package (or a mold) to form a system-in-package (SiP). However, mutual electromagnetic interference occurs between the dies or modules in the package, and external electromagnetic signals also interfere with the operation of these dies or modules, which may result in damages of the dies or modules and malfunction of the package incorporating these dies or modules. Hence, an improved package structure having a shielding structure is desired to provide a more effective electromagnetic shielding capability.

### SUMMARY

In one or more arrangements, a package structure includes a first electronic component, a first shielding layer, a second shielding layer, and an electrical connection element. The first shielding layer is over a lateral sidewall of the first electronic component. The second shielding layer is at a lateral side of the first shielding layer and spaced apart from the first shielding layer. The electrical connection element includes a reflowable material between the first shielding layer and the second shielding layer. The first shielding layer overlaps the second shielding layer in a direction substantially parallel to a top surface of the second shielding layer. An elevation of an upper surface of the electrical connection element is lower than at least one of an elevation of a top surface of the first shielding layer and an elevation of the top surface of the second shielding layer with respect to a bottom surface of the first electronic component.

In one or more arrangements, a package structure includes a first electronic component, an encapsulant, a first shielding layer, a second shielding layer, and a reflowable element. The encapsulant is spaced apart from the first electronic component by a gap. The first shielding layer is over the first electronic component and includes a first wall portion in the gap and tapering toward a bottom of the gap. The second shielding layer is over the encapsulant and includes a second wall portion in the gap tapering toward the bottom of the gap. The reflowable element is in the gap and connects the first shielding layer to the second shielding layer.

In one or more arrangements, a package structure includes an encapsulant, a first electronic component, a first shielding layer, a second shielding layer, and a first reflowable element. The first electronic component is exposed by the encapsulant and spaced apart from the encapsulant by a gap. The first shielding layer covers the first electronic component. The second shielding layer covers the encapsulant and is electrically connected to the first shielding layer. The first reflowable element is disposed in the gap and connecting a first portion of an edge of the first shielding layer to a first portion of an edge of the second shielding layer from a top view perspective, wherein a second portion of the edge of the first shielding layer and a second portion of the edge of the second shielding layer are exposed by the first reflowable element from the top view perspective.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a cross-section of a package structure in accordance with some arrangements of the present disclosure.

FIG. 1C is a cross-section of a package structure in accordance with some arrangements of the present disclosure.

FIG. 1D is a top view of a package structure in accordance with some arrangements of the present disclosure.

FIG. 2A is a cross-section of a package structure in accordance with some arrangements of the present disclosure.

FIG. 2B is a cross-section of a package structure in accordance with some arrangements of the present disclosure.

FIG. 2C is a top view of a package structure in accordance with some arrangements of the present disclosure.

FIG. 3A is a cross-section of a package structure in accordance with some arrangements of the present disclosure.

FIG. 3B is a cross-section of a package structure in accordance with some arrangements of the present disclosure.

FIG. 3C is a top view of a package structure in accordance with some arrangements of the present disclosure.

FIG. 4A to FIG. 4G illustrate various stages of an exemplary method of forming a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

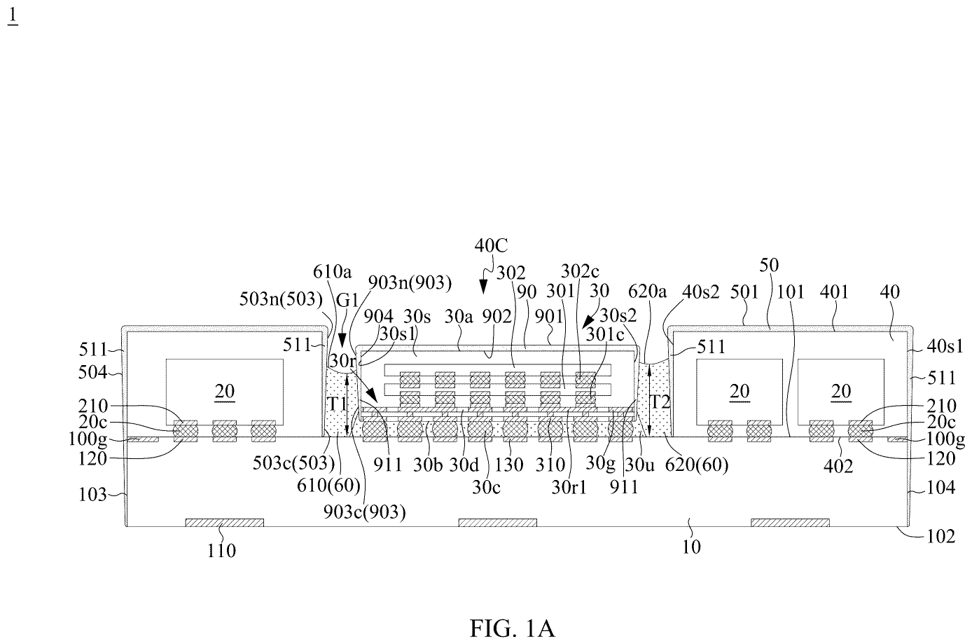

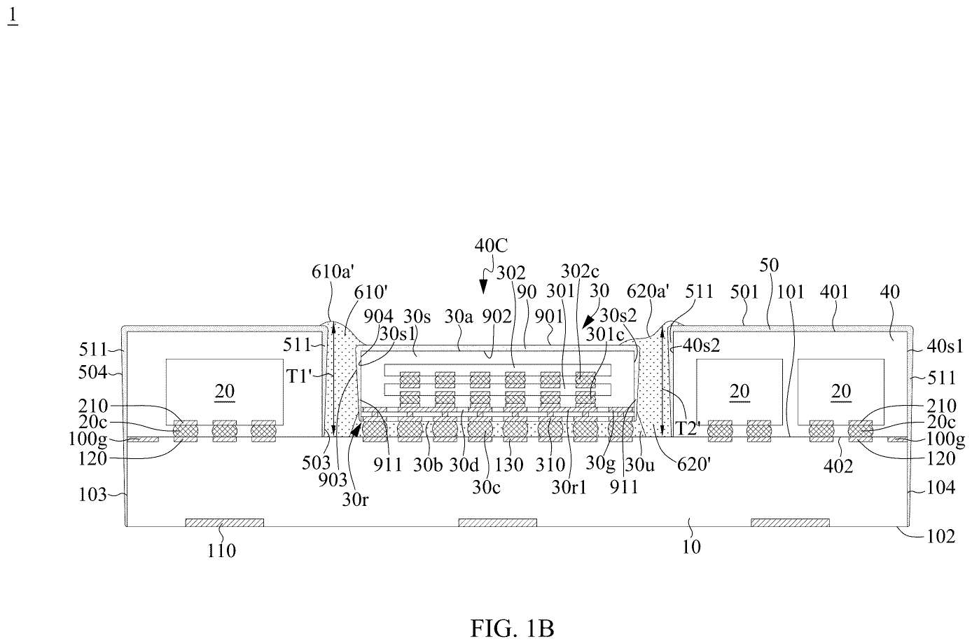

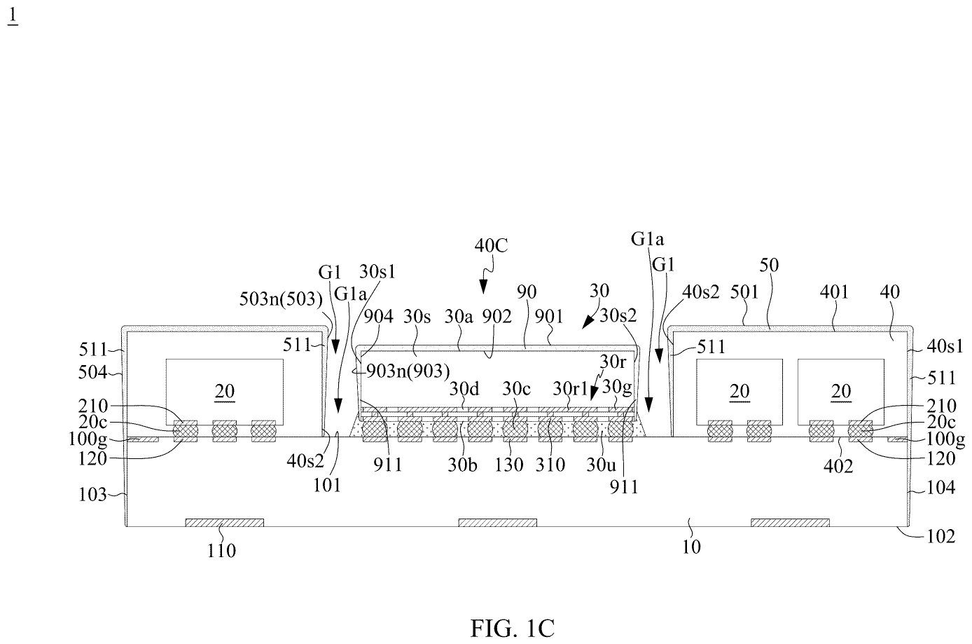

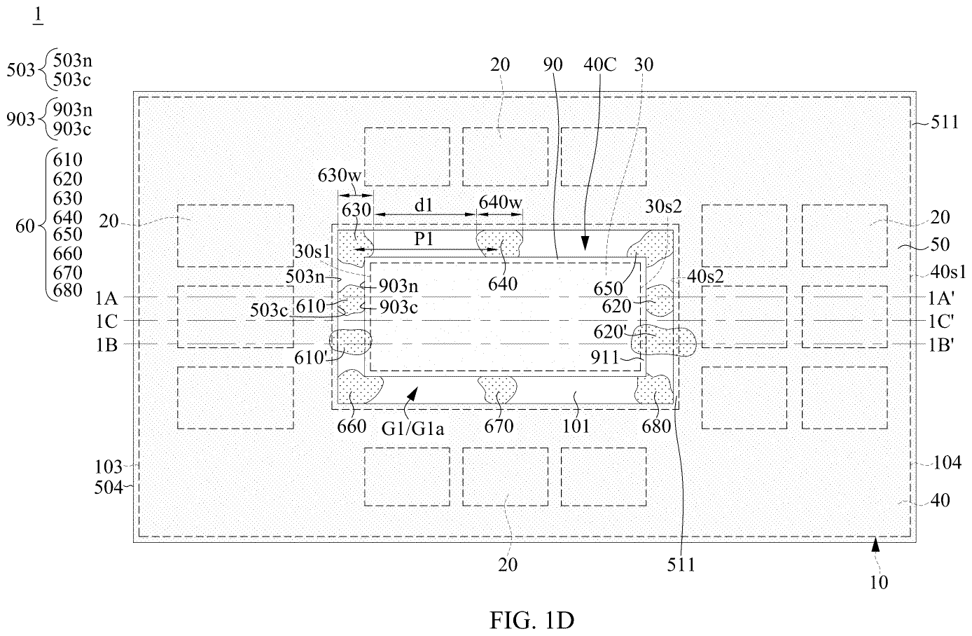

FIG. 1A is a cross-section of a package structure 1 in accordance with some arrangements of the present disclosure. FIG. 1B is a cross-section of a package structure 1 in accordance with some arrangements of the present disclosure. FIG. 1C is a cross-section of a package structure 1 in accordance with some arrangements of the present disclosure. FIG. 1D is a top view of a package structure 1 in accordance with some arrangements of the present disclosure. In some arrangements, FIG. 1A is a cross-section along a line 1A-1A′ in FIG. 1D. In some arrangements, FIG. 1B is a cross-section along a line 1B-1B′ in FIG. 1D. In some arrangements, FIG. 1C is a cross-section along a line 1B-1B′ in FIG. 1D. The package structure 1 may include a substrate 10, electronic components 20 and 30, an encapsulant 40, shielding layers 50 and 90, and an electrical connection element 60. The package structure 1 may be or include a multiple system shielding module (MSSM).

Embodiments of the present disclosure discuss a package structure including electronic components having different wafer nodes. The electronic components may be encapsulated separately according to their wafer nodes to be bonded to a substrate. For example, some of the electronic components having a higher or greater wafer node may be encapsulated to form one or more SiPs, and some other electronic components having a lower or less wafer node may be encapsulated separately. Next, only the SiPs and/or the electronic components that are identified as a known good dies (KGDs) may be used to form the package structure. Therefore, the yield can be increased. In addition, the a manufacturing cost for the electronic components having a higher or greater wafer node is less than a manufacturing cost for the electronic components having a lower or less wafer node. Therefore, encapsulating the electronic components separately is further advantageous to reducing the cost.

In addition, embodiments of the present disclosure discuss a package structure including gaps or trenches between encapsulants that encapsulate electronic components with different wafer nodes. The gaps or trenches may be narrow in widths and large in depths (e.g., a relatively high aspect ratio), and when depositing a shielding metal over the encapsulants and within the gaps or trenches, the as-formed shielding layer may easily break within the gaps or trenches to form separate shielding layer over separate encapsulants. By disposing an electrical connection element within the gaps or trenches, the shielding layers over different encapsulates can be electrically connected to each other and further electrically connected to the substrate. Therefore, the electromagnetic interference (EMI) shielding effect can be enhanced.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. In some arrangements, the substrate 10 includes a ceramic material, a metal plate, an organic substrate, or a leadframe. In some arrangements, the substrate 10 may include a two-layer substrate which includes a core layer and a conductive material and/or structure disposed on an upper surface and a bottom surface of the substrate 10. The conductive material and/or structure may include a plurality of conductive traces. The substrate 10 may include a surface 101, a surface 102 opposite to the surface 101, and lateral surfaces 103 and 104 extending between the surface 101 and the surface 102. In some arrangements, the substrate 10 includes conductive pads 120 and 130 exposed from the surface 101. In some arrangements, the substrate 10 includes conductive pads 110 exposed from the surface 102. In some arrangements, the substrate 10 includes one or more ground elements 100g exposed from at least one of the lateral surfaces 103 and 104.

The electronic components 20 may be disposed over the substrate 10. In some arrangements, the electronic component 20 includes conductive pads 210 facing and electrically connected to the substrate 10. In some arrangements, the electronic components 20 include surface mount devices (SMDs). Each of the electronic components 20 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the electronic component 20 includes an active device (e.g., a PMIC, an ASIC, or the like) or a passive device (e.g., a capacitor or the like).

The electronic component 30 may be disposed over the substrate 10. In some arrangements, a wafer node of the electronic component 30 is less than a wafer node of the electronic components 20. In some arrangements, a gate length of transistors of the electronic component 30 is less than a gate length of transistors of the electronic components 20. In some arrangements, the manufacturing cost for the electronic component 30 is higher than the manufacturing cost for the electronic components 20. In some arrangements, the electronic component 30 has a top surface 30a (also referred to as an upper surface), a bottom surface 30b (also referred to as a lower surface) facing the substrate 10, and lateral sidewalls 30s1 and 30s2 (also referred to as “lateral surfaces”).

In some arrangements, the electronic component 30 includes electronic devices 301 and 302, a redistribution layer (RDL) 30r, and an encapsulation layer 30s encapsulating the electronic devices 301 and 302. In some arrangements, a wafer node of the electronic devices 301 and 302 is less than a wafer node of the electronic components 20. In some arrangements, a gate length of transistors of the electronic devices 301 and 302 is less than a gate length of transistors of the electronic components 20. In some arrangements, the manufacturing cost for the electronic devices 301 and 302 is higher than the manufacturing cost for the electronic components 20. In some arrangements, the electronic device 302 is electrically connected to the electronic device 302 through conductive pads of the electronic device 302, connection elements 302c, and conductive pads of the electronic device 301. In some arrangements, the electronic device 301 is electrically connected to the RDL 30r through the conductive pads of the electronic device 301, connection elements 301c, and conductive pads 310. In some arrangements, the RDL 30r includes conductive layers 30r1 and dielectric layers 30d. The conductive layers 30r1 may include conductive traces and conductive vias. In some arrangements, the RDL 30r further includes a ground element 30g exposed by a lateral surface (e.g., the lateral sidewall 30s2) of the RDL 30r. The RDL 30r may further include conductive pads 310. The electronic component 30 may be or include system-on-chip (SoC), package-on-package (POP), MEMS, or the like. The electronic component 30 may be or include a system-in package (SiP). In some arrangements, the electronic component 30 is or includes a storage component, e.g., a double data rate synchronous dynamic random access memory (DDR SDRAM).

In some arrangements, the package structure 1 further includes connection elements 20c between the substrate 10 and the electronic components 20. In some arrangements, the electronic components 20 are electrically connected to the conductive pads 120 of the substrate 10 through the connection elements 20c and conductive pads 210. In some arrangements, the package structure 1 further includes connection elements 30c between the substrate 10 and the electronic component 30. In some arrangements, the connection elements 30c electrically connect the electronic component 30 to the substrate 10. In some arrangements, the electronic component 30 is electrically connected to the conductive pads 130 of the substrate 10 through the connection elements 30c and conductive pads 310. The connection elements 20c and 30c may include conductive bumps, solder elements, or the like.

In some arrangement, the package structure 1 further includes a protective element 30u between the substrate 10 and the electronic component 30. In some arrangement, the protective element 30u encapsulates the connection elements 30c. In some arrangements, the protective element 30u is or includes an underfill. The underfill may include an epoxy resin having fillers dispersed therein, a molding compound (e.g., an epoxy molding compound or other molding compound), polyimide (PI), a phenolic compound or material, a polymer material with silicone dispersed therein, or a combination thereof.

The encapsulant 40 may be disposed over the surface 101 of the substrate 10. In some arrangements, the encapsulant 40 encapsulates the electronic components 20. In some arrangements, the electronic component 30 is exposed by the encapsulant 40. In some arrangements, the electronic component 30 is spaced apart from the encapsulant 40 by a gap G1. In some arrangements, the encapsulant 40 defines an opening 40C exposing a portion of the top surface 101 of the substrate 10. The encapsulant 40 may have a top surface 401, a bottom surface 402 facing the substrate 10, and lateral sidewalls 40s1 and 40s2. The opening 40C may be defined by the lateral sidewall 40s2. The gap G1 may be defined by the lateral sidewall 30s2 and the lateral sidewall 40s2 and surround the electronic component 30. The encapsulant 40 may include an epoxy resin having fillers dispersed therein, a molding compound (e.g., an epoxy molding compound or other molding compound), PI, a phenolic compound or material, a polymer material with silicone dispersed therein, or a combination thereof. The encapsulant 40 may be referred to as a selective mold. The electronic components 20 encapsulated by the encapsulant 40 may be referred to as a system-in package (SiP).

The shielding layer 50 may be over the electronic components 20. In some arrangements, the shielding layer 50 covers at least the electronic components 20. In some arrangements, the shielding layer 50 further covers the lateral surfaces 103 and 104 of the substrate 10. In some arrangements, the ground element 100g is electrically connected to the shielding layer 50. In some arrangements, the shielding layer 50 contacts the encapsulant 40, the ground element 100g, the surface 101 of the substrate 10, and the lateral surfaces 103 and 104 of the substrate 10. In some arrangements, the ground element 100g is exposed by at least one of the lateral surfaces 103 and 104 and contacting the shielding layer 50. The shielding layer 50 may include a top surface 501 and lateral surfaces 503 and 504 (also referred to as “edges”). The lateral surface 503 may face the gap G1, and the lateral surface 504 may be opposite to the lateral surface 503. In some arrangements, the lateral surface 503 of the shielding layer 50 faces the shielding layer 90 and includes a portion 503n and a portion 503c. In some arrangements, the portion 503n of the lateral surface 503 is exposed to an insulating element, such as an air gap (e.g., the gap G1), and the portion 503c of the lateral surface 503 is spaced apart from the insulating element (e.g., the gap G1). The shielding layer 50 may be or include a conductive film, e.g., for example, aluminum (Al), copper (Cu), chromium (Cr), tin (Sn), gold (Au), silver (Ag), nickel (Ni), a mixture, an alloy, or other combination thereof. The shielding layer 50 may include multiple conductive layers.

In some arrangements, the shielding layer 50 includes wall portions 511 covering the lateral sidewall 40s1 of the encapsulant 40 and the lateral surfaces 103 and 104 of the substrate 10. In some arrangements, the wall portion 511 includes a tapered cross-sectional profile. In some arrangements, the wall portion 511 tapers in a direction from the encapsulant 40 toward the substrate 10. In some arrangements, the wall portion 511 tapers toward a bottom of the gap G1.

The electrical connection element 60 may be between the shielding layer 50 and the shielding layer 90. In some arrangements, the electrical connection element 60 electrically connects the shielding layer 50 to the shielding layer 90. In some arrangements, the electrical connection element 60 contacts the shielding layer 50 and the shielding layer 90. In some arrangements, the electrical connection element 60 contacts the wall portion 511 and the wall portion 911. In some arrangements, the electrical connection element 60 overlaps (or horizontally overlaps) the shielding layer 50 and the shielding layer 90 in a direction substantially parallel to the top surface 101 of the substrate 10. An upper surface of the electrical connection element 60 may be lower than an upper surface of at least one of the shielding layers with respect to the top surface 101 of the substrate 10. In some arrangements, the electrical connection element 60 includes a solder material, a conductive paste, or a conductive layer. The electrical connection element 60 may be referred to as a reflowable element. In some arrangements, the electrical connection element 60 is free from contacting the ground element 100g or the ground element 30g.

According to some arrangements of the present disclosure, the electrical connection element 60 electrically connects the shielding layer 50 to the shielding layer 90 and has an upper surface lower than upper surfaces of the shielding layers 50 and 90, and thus the electrical connection element 60 does not protrude beyond the upper surfaces of the shielding layers 50 and 90. Therefore, the electromagnetic interference (EMI) shielding effect can be enhanced without undesirably increasing the thickness of the package structure 1.

In some arrangements, the electrical connection element 60 is between the protective element 30u and the shielding layer 50. In some arrangements, the connection elements 30c are spaced apart from the electrical connection element 60 by the protective element 30u. In some arrangements, the electrical connection element 60 includes a tapered cross-sectional profile. In some arrangements, the electrical connection element 60 tapers in a direction away from the substrate 10. In some arrangements, the electrical connection element 60 includes a cross-sectional profile tapering away from a bottom of the gap G1.

In some arrangements, the electrical connection element 60 includes at least a portion 610 and a portion 620 at opposite sides (e.g., the lateral sidewalls 30s1 and 30s2) of the electronic component 30. In some arrangements, an elevation of an upper surface 610a of the portion 610 is different from an elevation of an upper surface 620a of the portion 620. In some arrangements, a thickness T1 of the portion 610 is different from a thickness T2 of the portion 620. In some arrangements, the thickness T1 and the thickness T2 may be up to about 90% of the depth of the gap G1.

In some arrangements, the electrical connection element 60 includes at least a portion 610′ and a portion 620′ at opposite sides (e.g., the lateral sidewalls 30s1 and 30s2) of the electronic component 30. In some arrangements, an elevation of an upper surface 610a′ of the portion 610′ is different from an elevation of an upper surface 620a′ of the portion 620′. In some arrangements, a thickness T1′ of the portion 610′ is different from a thickness T2′ of the portion 620′. In some arrangements, at least one of the portions 610′ and 620′ partially covers at least one of the top surface 901 of the shielding layer 90 and the top surface 501 of the shielding layer 50. According to some arrangements of the present disclosure, the connection interface or the bonding interface between the electrical connection element 60 and the shielding layer 50 can be increased, and thus the EMI shielding effect can be further enhanced.

In some arrangements, an elevation of at least one of upper surfaces 610a and 620a of the portions 610 and 620 of the electrical connection element 60 is lower than at least one of an elevation of a top surface 901 of the shielding layer 90 and an elevation of the top surface 501 of the shielding layer 50 with respect to the bottom surface 30b of the electronic component 30. In some arrangements, at least one of the upper surfaces 610a and 620a of the portions 610 and 620 of the electrical connection element 60 includes a non-planar surface. In some arrangements, the elevation of at least one of the upper surfaces 610a and 620a of the portions 610 and 620 of the electrical connection element 60 increases in a direction from the shielding layer 90 toward the shielding layer 50 or in a direction from the shielding layer 50 toward the shielding layer 90. In some arrangements, at least one of the upper surfaces 610a and 620a of the portions 610 and 620 of the electrical connection element 60 includes a curved surface. In some arrangements, at least one of the upper surfaces 610a and 620a of the portions 610 and 620 of the electrical connection element 60 is concave toward an inner portion of the electrical connection element 60.

The shielding layer 90 may be over the electronic component 30. In some arrangements, the shielding layer 90 is disposed over the top surface 30a and the lateral sidewalls 30s1 and 30s2 of the electronic component 30. In some arrangements, the ground element 30g is exposed by the lateral sidewall 30s2 and contacting the shielding layer 90. In some arrangements, the shielding layer 50 is at a lateral side of the shielding layer 90. In some arrangements, the shielding layer 90 is electrically connected to the shielding layer 50. In some arrangements, the shielding layer 90 is electrically connected to the shielding layer 50 through the electrical connection element 60. In some arrangements, the shielding layer 90 includes wall portions 911 covering the lateral sidewalls 30s1 and 30s2 of the electronic component 30. In some arrangements, the wall portion 911 tapers toward a bottom of the gap G1.

In some arrangements, the shielding layer 90 further has a lower surface 902 and lateral surfaces 903 and 904 (also referred to as “edges”). In some arrangements, the lateral surface 903 of the shielding layer 90 faces the shielding layer 50 and includes a portion 903n and a portion 903c. In some arrangements, the portion 903n of the lateral surface 903 is exposed to an insulating element, such as an air gap (e.g., the gap G1), and the portion 903c of the lateral surface 903 is spaced apart from the insulating element (e.g., the gap G1). In some arrangements, the gap G1 (or the air gap) is between the portion 503n of the lateral surface 503 of the shielding layer 50 and the portion 903n of the lateral surface 903 of the shielding layer 90. In some arrangements, the electrical connection element 60 contacts the portion 903c of the lateral surface 903 of the shielding layer 90 and the portion 503c of the lateral surface 503 of the shielding layer 50. The shielding layer 90 may be or include a conductive film, e.g., for example, Al, Cu, Cr, Sn, Au, Ag, Ni, stainless steel, a mixture, an alloy, or other combination thereof. The shielding layer 90 may include multiple conductive layers.

Referring to FIG. 1D, in some arrangements, the wall portion 511 surrounds the encapsulant 40. In some arrangements, the wall portion 511 includes a part contacting and surrounding the lateral sidewall 40s1 and a part contacting and surrounding the lateral sidewall 40s2.

Referring to FIG. 1D, in some arrangements, the electrical connection element 60 includes an irregular profile from a top view perspective. In some arrangements, the electrical connection elements 60 includes portions 610, 610′, 620, 620′, 630, 640, 650, 660, 670, and 680 separated from one another. The portions 610-680 may be referred to as reflowable elements. In some arrangements, one or more of the portions 610-680 may include one or more irregular profiles from a top view perspective. In some arrangements, a trench (e.g., the gap G1) is defined between the lateral surface 903 of the shielding layer 90 and the lateral surface 503 of the shielding layer 50, and the portions 610-680 of the electrical connection element 60 are disposed in the trench (or the gap G1). In some arrangements, the portions 610-680 are spaced apart from each other by a distance (e.g., a distance d1) greater than a width (e.g., a width 630w) of at least one of the portions 610-680. For example, the distance d1 between the portion 630 and the portion 640 is greater than the width 630w of the portion 630 and the width 640w of the portion 640. In some arrangements, the distance (e.g., the distance d1) between two adjacent ones of the portion 610-680 of the electrical connection element 60 is equal to or less than λ/16, wherein A is a wavelength of an operating frequency of the electronic component 30. In some arrangements, a pitch P1 between the portions 610-680 is greater than a width (e.g., a width 630w) of at least one of the portions 610-680. In some arrangements, the pitch P1 is equal to or less than λ/16, wherein A is a wavelength of an operating frequency of the electronic component 30. In some arrangements, the pitch P1 is equal to or less than about 7.5 mm, 6 mm, 5 mm, 4 mm, or 3 mm. In some arrangements, the pitch P1 is equal to greater than about 300 μm, 400 μm, 500 μm, 700 μm, or 1 mm. In some arrangements a width of the gap G1 is equal to or less than about 300 μm or 350 μm.

Referring to FIG. 1C and FIG. 1D, in some arrangements, a plurality of insulating elements (e.g., the air gaps G1a) may be spaced apart from one another and disposed in the gap G1. In some arrangements, the portions 610-680 of the electrical connection element 60 are between the insulating elements (e.g., the air gaps G1a).

In some arrangements, the portion 610 is disposed in the gap G1 and connects the portion 903c of the lateral surface 903 (or the edge) of the shielding layer 90 to the portion 503c of the lateral surface 503 (or the edge) of the shielding layer 50 from a top view perspective, In some arrangements, the portion 903n of the lateral surface 903 (or the edge) of the shielding layer 90 and the portion 503n of the lateral surface 503 (or the edge) of the shielding layer 50 are exposed by the portion 610 from the top view perspective. In some arrangements, the portion 610 contacts the portion 903c of the lateral surface 903 (or the edge) of the shielding layer 90 and the portion 503c of the lateral surface 503 (or the edge) of the shielding layer 50. In some arrangements, the portion 610′ is disposed in the gap G1 and spaced apart from the portion 610 contacts the shielding layer 90 and the shielding layer 50. In some arrangements, the portion 903n of the lateral surface 903 (or the edge) of the shielding layer 90 and the portion 503n of the lateral surface 503 (or the edge) of the shielding layer 50 are exposed by the portion 610′ from the top view perspective. In some arrangements, the portion 610′ partially covers the shielding layer 90 and the shielding layer 50.

According to some arrangements of the present disclosure, portions (e.g., the portions 503n) of the shielding layer 50 are spaced apart from portions (e.g., the portions 903n) of the shielding layer 90, and only portions (e.g., the portions 903c) of the shielding layer 90 are directly connected to the portions (e.g., the portions 503c) of the shielding layer 50 through the electrical connection element 60. Therefore, some of the noise can be directed out of the electronic component 30 around the shielding layer 90 through the electrical connection element 60, preventing it from resonating around the shielding layer 90 and resulting in noise amplification. Accordingly, the EMI shielding effect can be further enhanced.

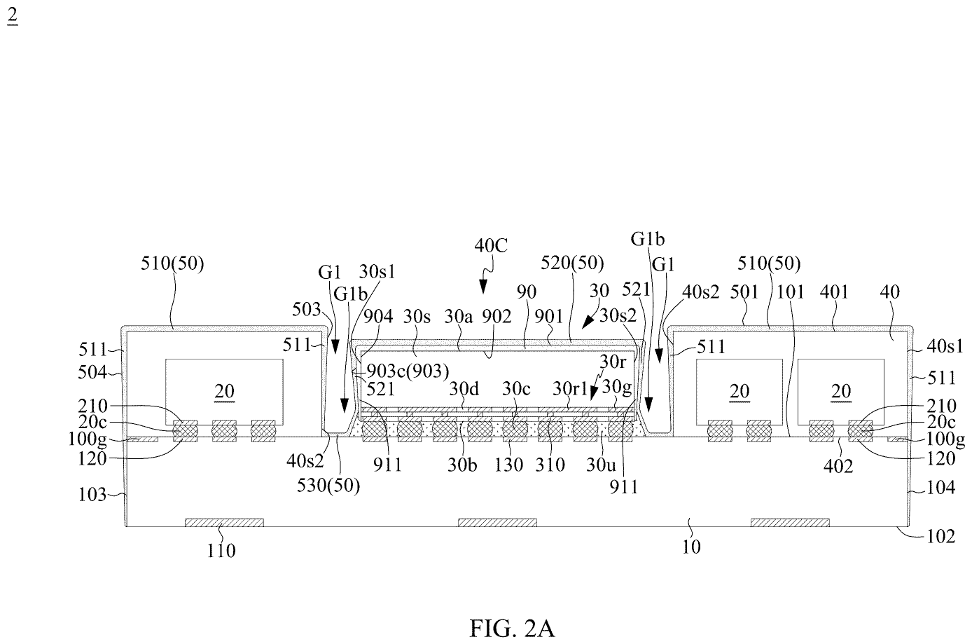

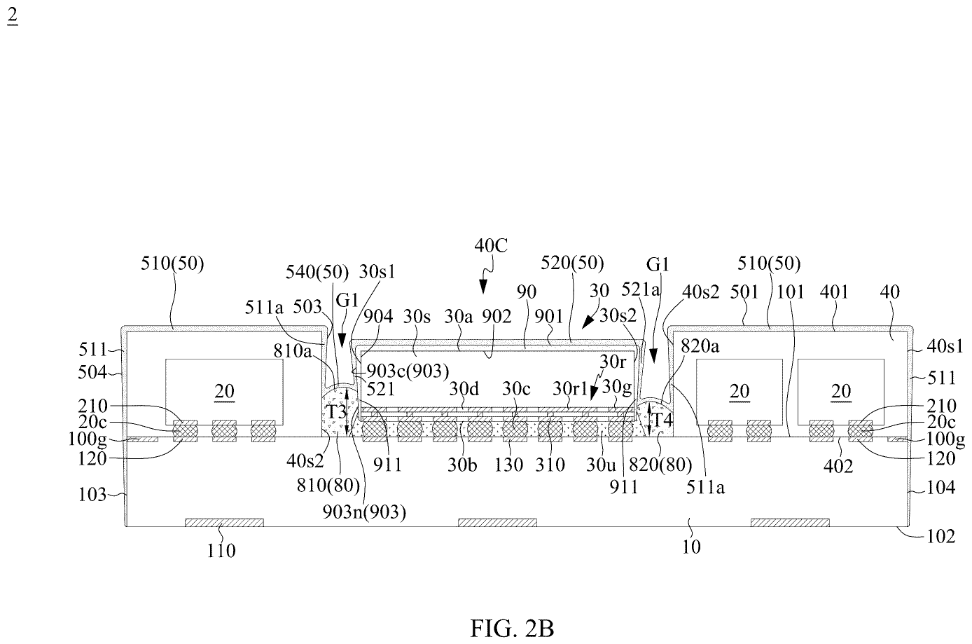

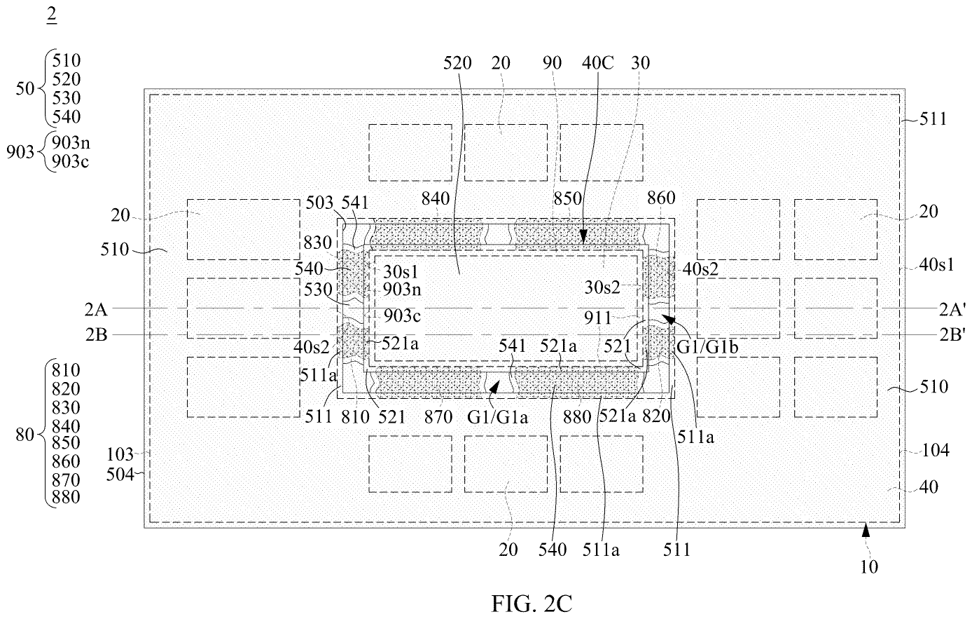

FIG. 2A is a cross-section of a package structure 2 in accordance with some arrangements of the present disclosure. FIG. 2B is a cross-section of a package structure 2 in accordance with some arrangements of the present disclosure. FIG. 2C is a top view of a package structure 2 in accordance with some arrangements of the present disclosure. In some arrangements, FIG. 2A is a cross-section along a line 2A-2A′ in FIG. 2C. In some arrangements, FIG. 2B is a cross-section along a line 2B-2B′ in FIG. 2C. The package structure 2 is similar to the package structure 1 in FIG. 1A to FIG. 1D, and the differences therebetween are described as follows.

In some arrangements, the shielding layer 50 includes a portion 510 contacting the encapsulant 40, a portion 520 contacting the shielding layer 90, and a portion 530 in the gap G1 and contacting the top surface 101 of the substrate 10. In some arrangements, the portion 510 includes the wall portions 511. In some arrangements, the portion 520 includes wall portions 521 contacting the wall portions 911 of the shielding layer 90. In some arrangements, the portion 530 connects the portion 510 to the portion 520.

Referring to FIG. 2B, in some arrangements, portions 503n of the lateral surface 503 of the shielding layer 50 are exposed to insulating elements, and portions 503c of the lateral surface 503 are spaced apart from the insulating elements. In some arrangements, the insulating elements include portions of an insulating layer 80. In some arrangements, the insulating layer 80 contacts the portions 903n of the lateral surface 903 of the shielding layer 90. The insulating layer 80 may include a dielectric material. The dielectric material may include one or more organic materials (e.g., phosphoric anhydride (PA), polyimide (PI), polybenzoxazole (PBO), epoxy, and an epoxy-based material) or one or more inorganic materials (e.g., silicon oxide, silicon nitride, glass, and ceramic). In some arrangements, the insulating layer 80 is or includes an underfill.

In some arrangements, the shielding layer 50 further includes a portion 540 over the insulating layer 80. In some arrangements, the shielding layer 50 is over a portion (also referred to as “a first portion” or “an upper portion”) of the lateral sidewall 40s2 of the encapsulant 40, and the insulating layer 80 contacts another portion (also referred to as “a second portion” or “a lower portion”) of the lateral sidewall 40s2 of the encapsulant 40. In some arrangements, the shielding layer 50 (or the portion 510) further includes wall portions 511a over the insulating layer 80 and connected to the portion 540. In some arrangements, the shielding layer 50 (or the portion 520) further includes wall portions 521a over the insulating layer 80 and connected to the portion 540. Referring to FIG. 2B and FIG. 2C, in some arrangements, a plurality of insulating elements may be spaced apart from each other and disposed in the gap G1. In some arrangements, the insulating elements include insulating portions 810, 820, 830, 840, 850, 860, 870, and 880 of the insulating layer 80. In some arrangements, the insulating portions 810-880 contact the encapsulant 40 and the shielding layer 90. In some arrangements, at least two of the insulating portions 810-880 have different thicknesses. For example, a thickness T3 of the insulating portion 810 is different from a thickness T4 of the insulating portion 820. In some arrangements, one or more of the insulating portions 810-880 may have one or more curved upper surfaces. For example, the insulating portions 810 and 820 have curved upper surfaces 810a and 820a. In some arrangements, the insulating portions 810-880 contact the lateral sidewall 40s2 and the protective element 30u.

Referring to FIG. 2B and FIG. 2C, in some arrangements, a plurality of air gaps G1b may be spaced apart from one another and disposed in the gap G1. In some arrangements, the insulating portions 810-880 of the insulating layer 80 are between the air gaps G1b.

According to some arrangements of the present disclosure, portions (e.g., the portions 903n) of the shielding layer 90 are spaced apart from the shielding layer 50 through the insulating portions 810-880, and only portions (e.g., the portions 903c) of the shielding layer 90 are directly connected to the shielding layer 50 (or the portion 540). Therefore, some of the noise can be directed out of the electronic component 30 around the shielding layer 90 through the portion 540 of the shielding layer 50, preventing it from resonating around the shielding layer 90 and resulting in noise amplification. Accordingly, the EMI shielding effect can be further enhanced.

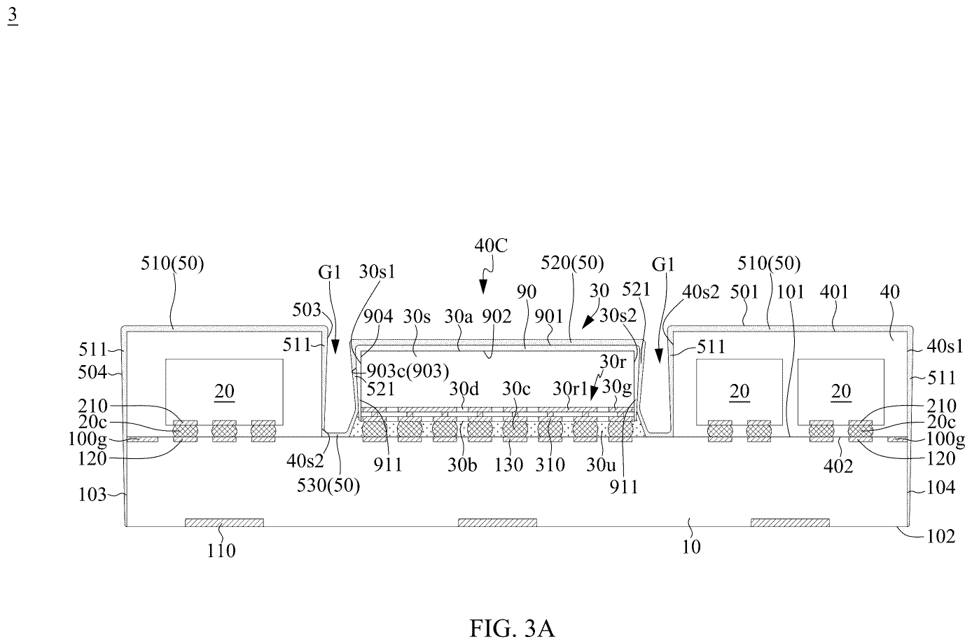

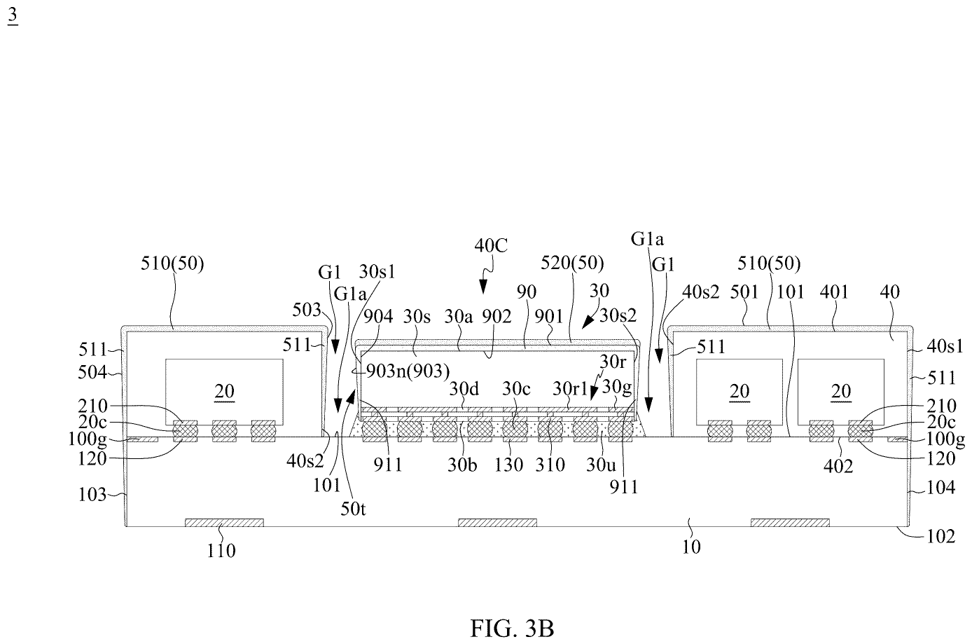

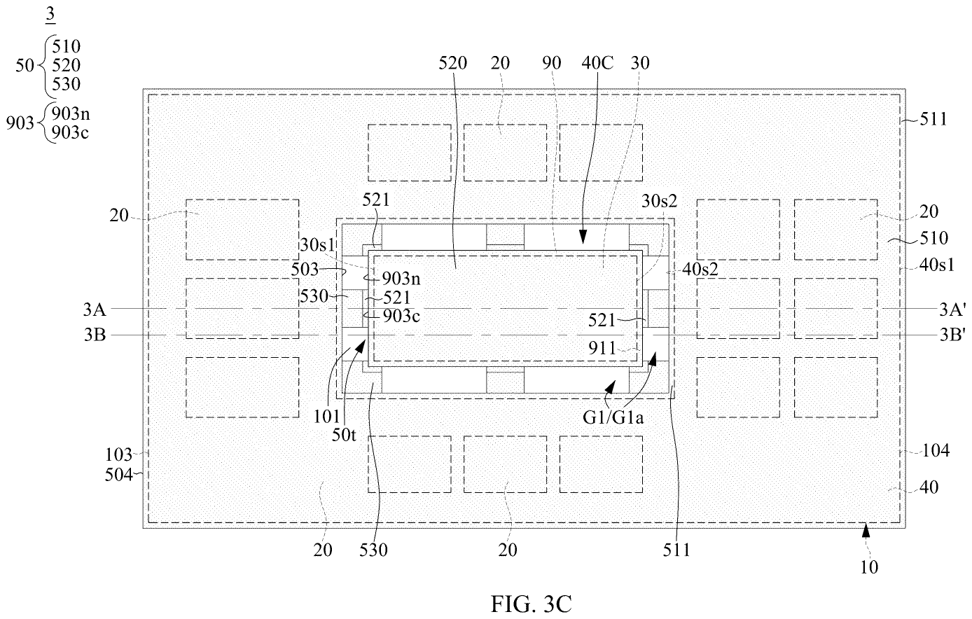

FIG. 3A is a cross-section of a package structure 3 in accordance with some arrangements of the present disclosure. FIG. 3B is a cross-section of a package structure 3 in accordance with some arrangements of the present disclosure. FIG. 3C is a top view of a package structure 3 in accordance with some arrangements of the present disclosure. In some arrangements, FIG. 3A is a cross-section along a line 3A-3A′ in FIG. 3C. In some arrangements, FIG. 3B is a cross-section along a line 3B-3B′ in FIG. 3C. The package structure 3 is similar to the package structure 1 in FIG. 1A to FIG. 1D and/or the package structure 2 in FIG. 2A to FIG. 2C, and the differences therebetween are described as follows.

In some arrangements, the portions 903c of the lateral surface 903 of the shielding layer 90 contact the shielding layer 50. In some arrangements, the shielding layer 50 (or the wall portions 521) may be further disposed on the portions 903c of the lateral surface 903 of the shielding layer 90 and define openings 50t exposing the portions 903n of the lateral surface 903 of the shielding layer 90. In some arrangements, the portions 930n of the lateral surface 903 and portions of the top surface 101 are exposed to air gaps G1a.

In some arrangements, the portions 903n of the lateral surface 903 and the portions of the top surface 101 exposed to the air gaps G1a may be formed by covering these areas by tapes before forming the shielding layer 50. In some arrangements, the shielding layer 50 may be formed by depositing a shielding material on the encapsulant 40, the shielding layer 90, and the top surface 101 exposed to the gap G1, and the portions 903n of the lateral surface 903 and portions of the top surface 101 covered by the tapes are free from being covered by the shielding material. Next, after the shielding layer 50 is formed, the tapes are removed, and then the portions 903n of the lateral surface 903 and the portions of the top surface 101 exposed to the air gaps G1a without being covered by the shielding layer 50.

According to some arrangements of the present disclosure, portions (e.g., the portions 903n) of the shielding layer 90 are spaced apart from the shielding layer 50 through the air gaps G1a, and only portions (e.g., the portions 903c) of the shielding layer 90 are directly connected to the shielding layer 50 (or the wall portions 511) through the portion 530. Therefore, some of the noise can be directed out of the electronic component 30 around the shielding layer 90 through the portion 530 of the shielding layer 50, preventing it from resonating around the shielding layer 90 and resulting in noise amplification. Accordingly, the EMI shielding effect can be further enhanced.

Table 1 illustrates EMI simulation results of embodiments and comparative embodiments of the present disclosure. Five modules A, B, C, D, and E were tested, and the results are provided in Table 1. Module A was a package structure design in accordance with the structure illustrated in FIG. 1A without the shielding layers 50 and 90. Module B was a package structure design in accordance with the structure illustrated in FIG. 1A without the shielding layer 90. Module C was a package structure design in accordance with the structure illustrated in FIG. 1A with the shielding layer 90 floated to ground. Module D was a package structure design in accordance with the structure illustrated in FIG. 1A with the gap G1 between the shielding layers 50 and 90 entirely filled with a shielding material. Module E was a package structure design in accordance with the structure illustrated in FIG. 1A with the pitch P1 less than 7.5 mm. Table 1 shows maximum electric field intensities at various frequencies. The maximum electric field intensities were measured at elevated surfaces above top surfaces of the package structures.

TABLE 1

| | | A (V/m) | B (V/m) | C (V/m) | D (V/m) | E (V/m) |
|---|---|---|---|---|---|---|
| 0.5 | GHz | 102.65 | 105.46 | 242.66 | 8.93 | 5.83 |
| 1 | GHz | 65.47 | 57.87 | 82.97 | 17.18 | 10.22 |
| 2 | GHz | 53.02 | 48.53 | 24.81 | 16.35 | 11.77 |
| 3 | GHz | 37.87 | 38.47 | 63.13 | 16.69 | 13.25 |
| 4 | GHz | 96.55 | 98.92 | 81.54 | 42.97 | 39.64 |
| 5 | GHz | 97.25 | 88.24 | 149.24 | 41.02 | 38.22 |

Table 1 shows that module E has a lowest maximum electric field intensity, indicating a lowest EMI radiation was measured. In addition, the module E is provided with a better EMI shielding effect than the module D, which indicates that the design of the shielding layers 50 and 90 partially connected is provided with a better EMI shielding effect than the design of the shielding layers 50 and 90 entirely connected.

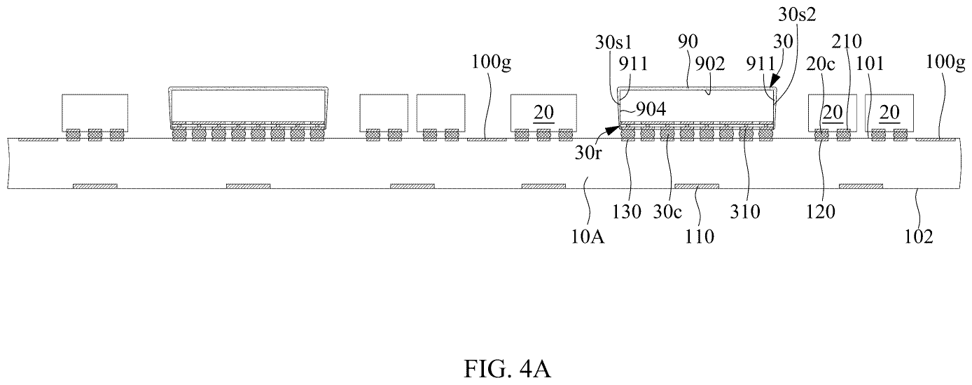

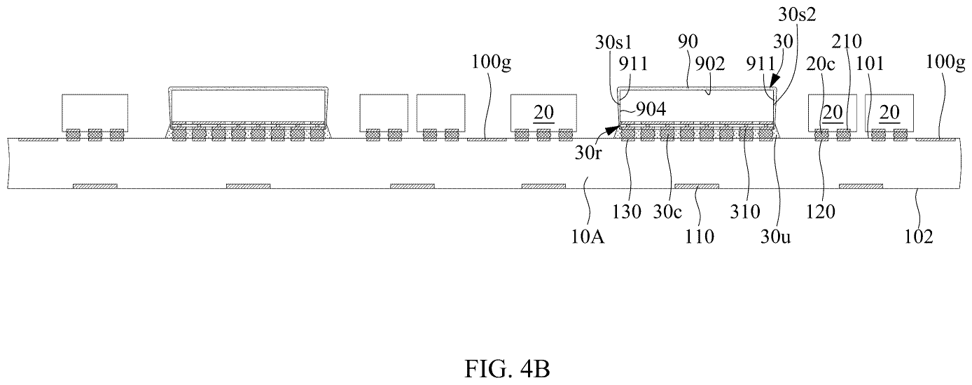

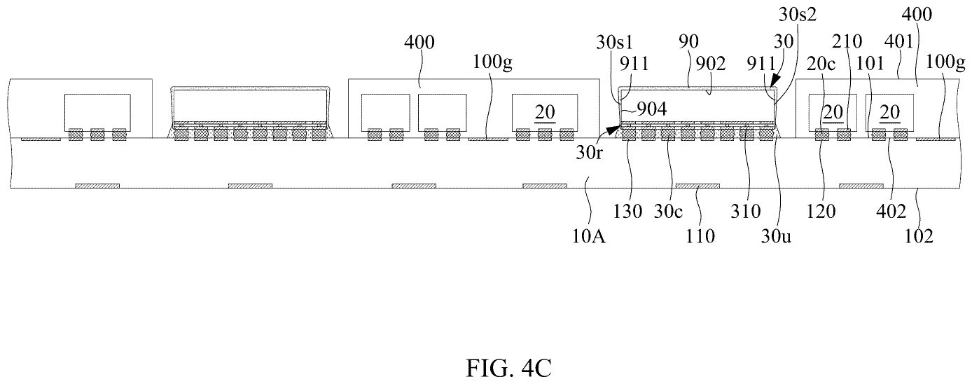

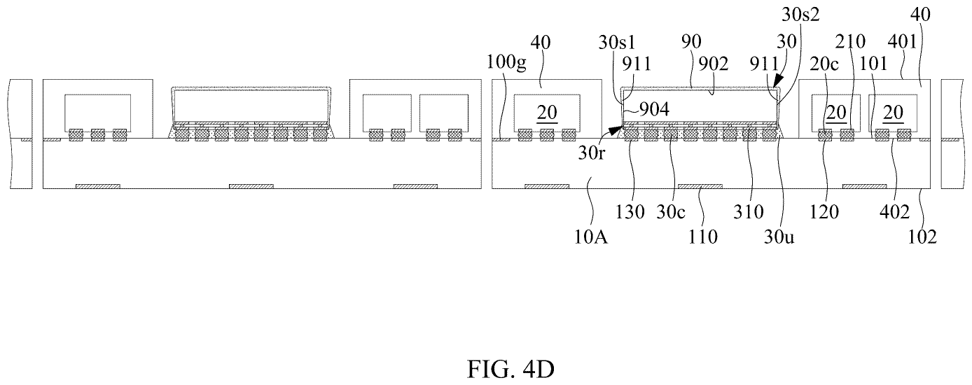

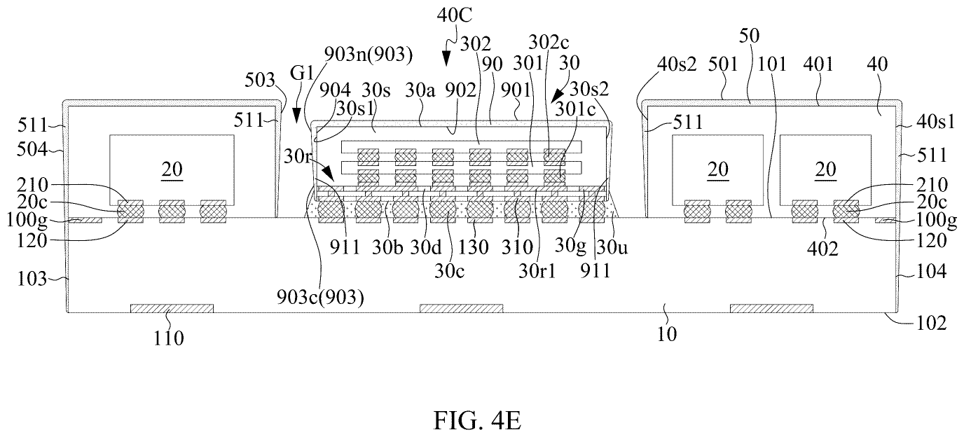

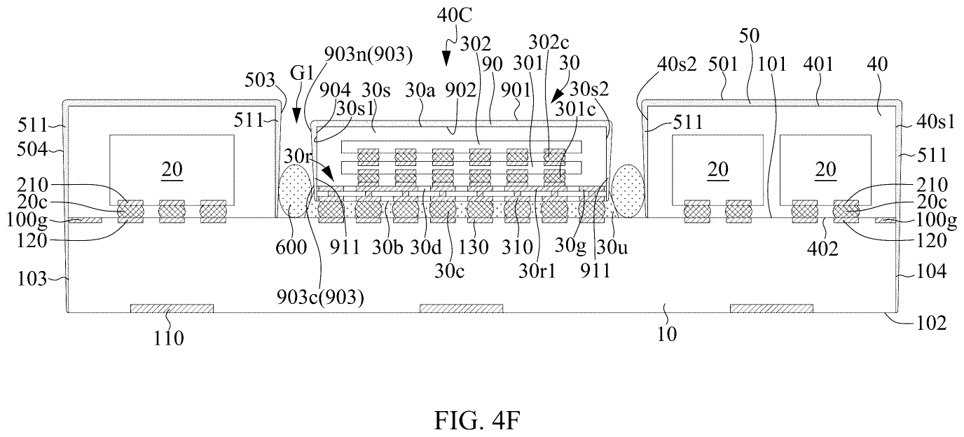

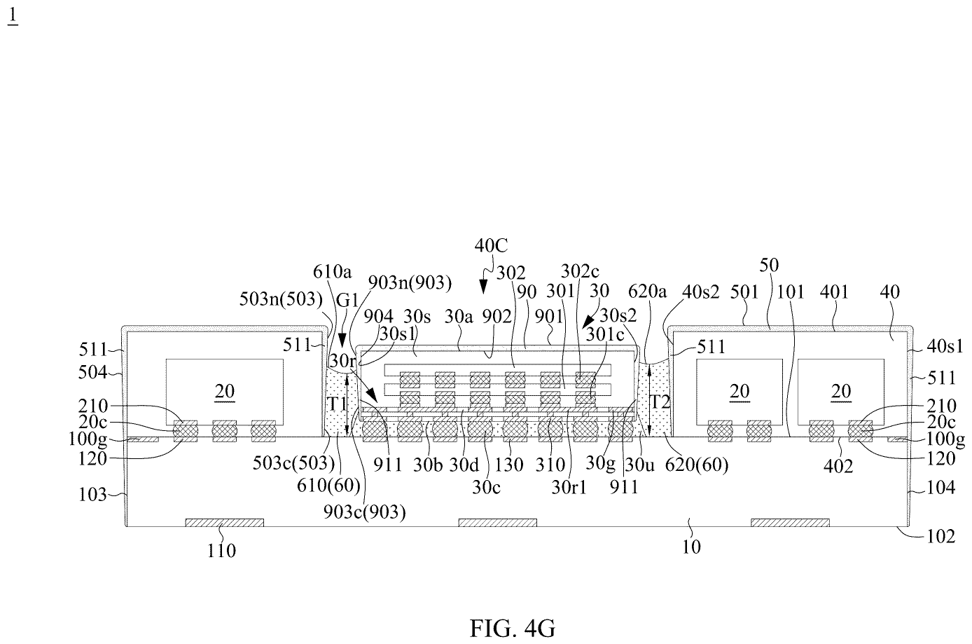

FIG. 4A to FIG. 4G illustrate various stages of an exemplary method of forming a package structure 1 in accordance with some arrangements of the present disclosure.

Referring to FIG. 4A, a substrate layer 10A including conductive pads 110, 120, and 130 and ground elements 100g may be provided, and electronic components 20 and 30 may be connected to the substrate layer 10A through connection elements 20c and 30c. In some arrangements, shielding layers 90 are formed over the electronic components 20.

Referring to FIG. 4B, a protective element 30u may be formed to encapsulate the connection elements 30c.

Referring to FIG. 4C, an encapsulant layer 400 may be disposed to encapsulate the electronic components 20 without encapsulating the electronic components 30. In some arrangements, the electronic components 30 are exposed by the encapsulant layer 400.

Referring to FIG. 4D, a singulation operation may be performed to form a plurality of singulated structures. In some arrangements, the substrate layer 10A and the encapsulant layer 400 may be divided into a plurality of substrates 10 and encapsulants 40. In some arrangements, the singulation operation may be performed by a mechanical cutting operation, e.g., by a mechanical sawing operation.

Referring to FIG. 4E, a shielding layer 50 may be formed to cover the encapsulant 40. In some arrangements, the electronic component 30 and the shielding layer 90 are exposed by the encapsulant 40 and the shielding layer 50. The shielding layer 50 may be formed by a physical vapor deposition (PVD) operation. In some arrangements, the shielding layer 50 and the shielding layer 90 are spaced apart from each other by a gap G1.

Referring to FIG. 4F, reflowable elements 600 may be disposed in the gap G1. In some arrangements, the reflowable elements 600 are or include solder elements, e.g., solder balls.

Referring to FIG. 4G, a reflow operation may be performed on the reflowable elements 600 to form an electrical connection element 60 in the gap G1 and connecting the shielding layers 50 and 90. In some arrangements, the electrical connection element 60 includes a plurality of portions (e.g., portions 610 and 620) formed from the reflowable elements 600. As such, the package structure 1 illustrated in FIGS. 1A-1C may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a first electronic component;
a first shielding layer over a lateral sidewall of the first electronic component;
a second shielding layer at a lateral side of the first shielding layer and spaced apart from the first shielding layer; and
an electrical connection element comprising a reflowable material between the first shielding layer and the second shielding layer, wherein the first shielding layer overlaps the second shielding layer in a direction substantially parallel to a top surface of the second shielding layer, and an elevation of an upper surface is lower than at least one of an elevation of a top surface of the first shielding layer and an elevation of the top surface of the second shielding layer with respect to a bottom surface of the first electronic component.

2. The package structure as claimed in claim 1, wherein the upper surface of the electrical connection element comprises a curved surface.

3. The package structure as claimed in claim 2, wherein the upper surface of the electrical connection element is concave toward an inner portion of the electrical connection element.

4. The package structure as claimed in claim 1, wherein the upper surface of the electrical connection element comprises a non-planar surface, and the elevation of the upper surface of the electrical connection element increases in a direction from the first shielding layer toward the second shielding layer.

5. The package structure as claimed in claim 1, wherein the electrical connection element comprises a first portion and a second portion at opposite sides of the first electronic component, and an elevation of an upper surface of the first portion is different from an elevation of an upper surface of the second portion.

6. The package structure as claimed in claim 5, wherein at least one of the first portion and the second portion partially covers at least one of the top surface of the first shielding layer and the top surface of the second shielding layer.

7. The package structure as claimed in claim 1, further comprising a substrate and a protective element between the substrate and the first electronic component, wherein the electrical connection element is between the protective element and the second shielding layer.

8. The package structure as claimed in claim 7, further comprising a plurality of connection elements electrically connecting the first electronic component to the substrate, wherein the connection elements are spaced apart from the electrical connection element by the protective element.

9. The package structure as claimed in claim 1, wherein the electrical connection element comprises a solder material.

10. The package structure as claimed in claim 9, wherein the electrical connection element comprises a tapered cross-sectional profile.

11. The package structure as claimed in claim 9, wherein the electrical connection element comprises an irregular profile from a top view perspective.

12. The package structure as claimed in claim 1, wherein a trench is defined between a lateral surface of the first shielding layer and a lateral surface of the second shielding layer, and the electrical connection element comprises a first portion and a second portion disposed in the trench and spaced apart from each other by a distance greater than a width of the first portion.

13. The package structure as claimed in claim 12, wherein the distance between the first portion and the second portion of the electrical connection element is equal to or less than λ/16, wherein λ is a wavelength of an operating frequency of the first electronic component.

14. A package structure, comprising:
a first electronic component;
an encapsulant spaced apart from the first electronic component by a gap;
a first shielding layer over the first electronic component and comprising a first wall portion in the gap and tapering toward a bottom of the gap;
a second shielding layer over the encapsulant and comprising a second wall portion in the gap and tapering toward the bottom of the gap; and
a reflowable element in the gap and connecting the first shielding layer to the second shielding layer.

15. The package structure as claimed in claim 14, wherein the reflowable element contacts
the first wall portion and the second wall portion.

16. The package structure as claimed in claim 14, wherein the reflowable element comprises
a cross-sectional profile tapering away from the bottom of the gap.

17. A package structure, comprising:
an encapsulant;
a first electronic component exposed by the encapsulant and spaced apart from the encapsulant by a gap;
a first shielding layer covering the first electronic component;
a second shielding layer covering the encapsulant and electrically connected to the first shielding layer; and
a first reflowable element disposed in the gap and connecting a first portion of an edge of the first shielding layer to a first portion of an edge of the second shielding layer from a top view perspective, wherein a second portion of the edge of the first shielding layer and a second portion of the edge of the second shielding layer are exposed by the first reflowable element from the top view perspective.

18. The package structure as claimed in claim 17, wherein the first reflowable element contacts the first portion of the edge of the first shielding layer and the first portion of the edge of the second shielding layer.

19. The package structure as claimed in claim 17, further comprising a second reflowable element disposed in the gap and spaced apart from the first reflowable element, wherein the second reflowable element contacts the first shielding layer and the second shielding layer, and the second portion of the edge of the first shielding layer and the second portion of the edge of the second shielding layer are exposed by the second reflowable element from the top view perspective.

20. The package structure as claimed in claim 19, wherein the second reflowable element partially covers the first shielding layer and the second shielding layer.
